(19) United States
(12) Patent Application Publication
(10) Pub. No.: US 2026/0134936 A1
(43) Pub. Date: May 14, 2026

(54) FLASH MEMORY QUALITY GRADING METHOD, FLASH MEMORY QUALITY GRADING APPARATUS, AND NON-TRANSITORY COMPUTER-READABLE STORAGE MEDIUM

(71) Applicant: Hosin Global Electronics Co., LTD, Shenzhen (CN)

(72) Inventors: SIU TUNG LAM, Shenzhen (CN); Song XIA, Shenzhen (CN); Hangqi GUO, Shenzhen (CN); Xinyao SONG, Shenzhen (CN); Yuwei XIA, Shenzhen (CN); Yawen Chuang, Shenzhen (CN)

(73) Assignee: Hosin Global Electronics Co., LTD, Shenzhen (CN)

(21) Appl. No.: 19/335,102

(22) Filed: Sep. 22, 2025

(30) Foreign Application Priority Data
Nov. 12, 2024 (CN) 2024116076377

(51) Int. Cl. G11C 29/42; G06F 18/2413; G11C 29/12

(52) U.S. Cl. CPC G11C 29/42; G06F 18/24137; G11C 29/12005

(57) ABSTRACT

The disclosure disclose a flash memory quality grading method including: testing a plurality of flash memory dies to obtain a bit error count and a read voltage offset value corresponding to each die; calculating a normalized value of the bit error count and a normalized value of the read voltage offset value for each of the plurality of flash memory dies; assigning a first weight value for the bit error count and a second weight value for the read voltage offset value based on an application type; calculating an evaluation score for each of the plurality of flash memory dies based on the normalized value of the bit error count, the normalized value of the read voltage offset value, the first weight value, and the second weight value; and categorizing the plurality of flash memory dies into a plurality of quality grades based on the evaluation score of each die.

This non-provisional patent application claims priority under 35 U. S. C. § 119 from Chinese Patent Application No. 202411607637.7 filed on Nov. 12, 2024, the entire content of which is incorporated herein by reference.

### TECHNICAL FIELD

This disclosure relates to the field of storage technology, specifically to a flash memory quality grading method, a flash memory quality grading apparatus and a non-transitory computer-readable storage medium.

### BACKGROUND

In the manufacturing process of the storage technology field, a plurality of flash memory dies (storage chips) can be obtained from a single wafer. Due to limitations in the manufacturing process and technology, the quality of these flash memory dies varies among different dies, and there may be significant differences in storage performance.

Nowadays, storage demands are categorized into different levels, including enterprise-level, industrial-level, automotive-level, and consumer-level. Different level have different requirements for the quality of flash memory dies. If flash memory dies with poor quality are selected for the enterprise-level storage, it can cause serious security risks. Conversely, if flash memory dies with very good quality are selected for the consumer-level storage, it can result in a certain waste of storage performance. Therefore, the current classification of flash memory dies is relatively rough and inaccurate, with low accuracy in die grade classification.

### SUMMARY

The embodiments of the disclosure provide a flash memory quality grading method, a flash memory quality grading apparatus, and a non-transitory computer-readable storage medium, which can perform normalized weighted averaging on the bit error count and the read voltage offset value for flash memory dies to calculate corresponding evaluation score and classify the dies based on these evaluation scores, thereby improving the accuracy of flash memory die classification.

The embodiments of the disclosure provide a flash memory quality grading method applied to a flash memory quality grading apparatus. The flash memory quality grading apparatus comprises a processor and a memory controller, and the method includes steps of: testing a plurality of flash memory dies to obtain a bit error count and a read voltage offset value corresponding to each flash memory die; calculating a normalized value of the bit error count and a normalized value of the read voltage offset value for each of the plurality of flash memory dies; assigning a first weight value for the bit error count and a second weight value for the read voltage offset value based on an application type; calculating an evaluation score for each of the plurality of flash memory dies based on the normalized value of the bit error count, the normalized value of the read voltage offset value, the first weight value, and the second weight value; and categorizing the plurality of flash memory dies into a plurality of quality grades based on the evaluation score of each flash memory die.

In one embodiment, calculating the normalized value of the bit error count and the normalized value of the read voltage offset value comprises: acquiring a maximum bit error count value, a minimum bit error count value, a maximum read voltage offset value, and a minimum read voltage offset value from the plurality of flash memory dies; calculating the normalized value of the bit error count for each flash memory die based on its bit error count, the maximum bit error count value, and the minimum bit error count value; and calculating the normalized value of the read voltage offset value for each flash memory die based on its read voltage offset value, the maximum read voltage offset value, and the minimum read voltage offset value.

In one embodiment, calculating the evaluation score comprises: calculating a first product of the normalized value of the bit error count and the first weight value for each flash memory die; calculating a second product of the normalized value of the read voltage offset value and the second weight value for each flash memory die; and summing the first product and the second product to obtain the evaluation score for each flash memory die.

In one embodiment, categorizing the plurality of flash memory dies comprises: randomly selecting a preset number of evaluation scores from all evaluation scores as initial centroids; calculating a distance from each evaluation score to each initial centroid; assigning each evaluation score to a cluster corresponding to its nearest initial centroid to form a preset number of clusters; calculating a mean value of all evaluation scores in each cluster and setting the mean value as a new centroid; iteratively updating the clusters and centroids until a convergence condition is met; and classifying the flash memory dies based on final clusters obtained after iteration.

In one embodiment, iteratively updating the clusters and centroids comprises: calculating a distance from each evaluation score to each current centroid; reassigning each evaluation score to a cluster corresponding to its nearest current centroid; calculating a new mean value of all evaluation scores in each new cluster and setting the new mean value as an updated centroid; and repeating the calculating, reassigning, and calculating steps until the centroids remain substantially unchanged between iterations.

In one embodiment, classifying the flash memory dies based on the final clusters comprises: identifying flash memory dies in a cluster associated with a centroid having a smallest value as a highest quality grade; identifying flash memory dies in a cluster associated with a centroid having a next smallest value as a medium quality grade; and identifying flash memory dies in a cluster associated with a centroid having a largest value as a lowest quality grade.

In one embodiment, the method further includes steps of: calculating a variance of evaluation scores within each quality grade; calculating a mean difference of evaluation scores between different quality grades; and adjusting a number of the quality grades based on the calculated variances and mean differences.

The embodiments of the disclosure also provide a flash memory quality grading apparatus, including a memory controller, configured to test a plurality of flash memory dies to obtain a bit error count and a read voltage offset value corresponding to each flash memory die; and a processor, coupled to the memory controller, and configured to:
Calculate a normalized value of the bit error count and a normalized value of the read voltage offset value for each of the plurality of flash memory dies;
Assign a first weight value for the bit error count and a second weight value for the read voltage offset value based on an application type;
Calculate an evaluation score for each of the plurality of flash memory dies based on the normalized value of the bit error count, the normalized value of the read voltage offset value, the first weight value, and the second weight value; and
categorize the plurality of flash memory dies into a plurality of quality grades based on the evaluation score of each flash memory die.

The embodiments of the disclosure also provide a non-transitory computer-readable storage medium storing instructions that, when executed by a processor of a computing device, cause the computing device to perform the above flash memory quality grading method.

The embodiments of the disclosure also provide a computer device comprising a memory and a processor, wherein the processor invokes the computer program stored in the memory to perform the flash memory quality grading method as described above.

The flash memory quality grading method, the non-transitory computer-readable storage medium, the flash memory quality grading apparatus, and the computer device provided by the embodiments of the disclosure can test a plurality of flash memory dies to obtain a bit error count and a read voltage offset value corresponding to each flash memory die by the memory controller, and can calculate normalized values, assign weight values, calculate the evaluation scores for the plurality of flash memory dies, and categorizing the plurality of flash memory dies into a plurality of quality grades The solution provided by the embodiments of the disclosure can perform normalized weighted averaging on the bit error count and the read voltage offset value for flash memory dies to calculate corresponding evaluation scores and classify the dies based on these evaluation scores, thereby improving the accuracy of flash memory die classification.

### BRIEF DESCRIPTION OF THE DRAWINGS

To more clearly illustrate the technical solutions in the embodiments of the disclosure, the drawings used in the description of the embodiments will be briefly introduced below. It is obvious that the drawings in the following description are merely some embodiments of the disclosure, and for those skilled in the art, other drawings can be obtained based on these drawings without creative efforts.

FIG. 1 is a schematic flowchart of a flash memory quality grading method provided by an embodiment of the disclosure.

FIG. 2 is another schematic flowchart of a flash memory quality grading method provided by an embodiment of the disclosure.

FIG. 3 is a schematic structural diagram of a flash memory quality grading apparatus provided by an embodiment of the disclosure.

FIG. 4 is another schematic structural diagram of a flash memory quality grading apparatus provided by an embodiment of the disclosure.

FIG. 5 is a schematic structural diagram of a computer device provided by an embodiment of the disclosure.

### DETAILED DESCRIPTION OF THE EMBODIMENTS

The technical solutions in the embodiments of the disclosure will be clearly and completely described below in conjunction with the accompanying drawings in the embodiments of the disclosure. It is obvious that the described embodiments are merely a part, rather than all, of the embodiments of the disclosure. All other embodiments obtained by those skilled in the art based on the embodiments of the disclosure without creative efforts shall fall within the protection scope of the disclosure.

It should be noted that, in this document, the terms “include,” “comprise”, or any other variants thereof are intended to encompass a non-exclusive inclusion, such that a process, method, article, or device that includes a series of elements not only includes those elements but also includes other elements not explicitly listed or inherent to such a process, method, article, or device. Without further limitations, an element defined by the statement “including a . . . ” does not exclude the existence of additional identical elements in the process, method, article, or device that includes the element. Furthermore, components, features, or elements with the same names in different embodiments of the disclosure may have the same or different meanings, and their specific meanings need to be determined based on their explanations in the specific embodiments or further in conjunction with the context of the specific embodiments.

The embodiments of the disclosure provide a flash memory quality grading method, a non-transitory computer-readable storage medium, and a flash memory quality grading apparatus. Specifically, the flash memory quality grading method in the embodiments of the disclosure can be executed by a computing device or a server, wherein the computing device can be a terminal device. The terminal device can be a smartphone, a tablet computer, a notebook computer, a touch screen, a game console, a personal computer (PC), a personal digital assistant (PDA), a smart home device, etc. The terminal device may also include a client, which can be a media playback client, instant messaging client, or the like.

The flash memory quality grading method applied to a flash memory quality grading apparatus. The flash memory quality grading apparatus includes a processor and a memory controller, The memory controller is a controller of a Solid State Drive (SSD). The processor is a CPU of the computing device.

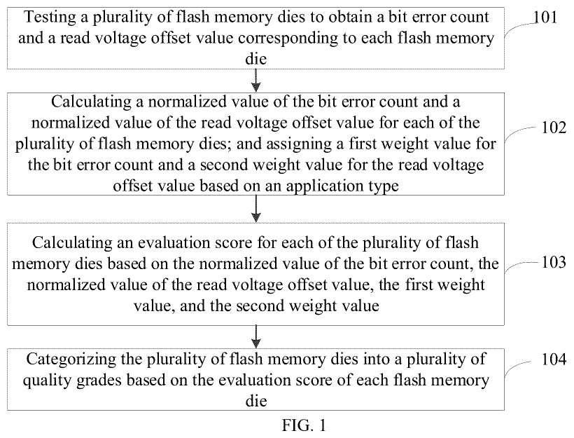

Referring to FIG. 1, a flow of the flash memory quality grading method can be as follows:

In step 101: testing a plurality of flash memory dies to obtain a bit error count and a read voltage offset value corresponding to each flash memory die.

In one embodiment, the flash memory is a non-volatile storage technology that can retain data when power is lost. The flash memory dies (or referred to as flash memory dies or flash memory units) in the disclosure are the most fundamental components that constitute flash memory devices, including but not limited to NAND flash memory and NOR flash memory. In this embodiment, the step 101 is performed by the memory controller.

Specifically, when collecting the bit error count for flash memory dies, specific test programs can be written or existing test tools can be utilized to perform read and write operations on the flash memory dies and record types of error correction code (ECC) used during data transmission and related parameters, which may include a bit count of the error correction code, and coding efficiency, etc. Then, a log file or database can be used to record the bit error count for each flash memory die. For example, if ECC detects ten bit error counts in 1 KB of data, then the ECC value (bit error count) is ten. This value can be used to evaluate the data integrity and reliability of the storage medium. A lower bit error count indicates better quality of the storage medium or a relatively stable storage environment.

Furthermore, since the electrical characteristics of flash memory dies change over time, it is necessary to periodically measure the read voltage offset value. In one embodiment, the voltage values of memory cells in different states can be read and compared with a predetermined reference voltage to obtain the read voltage offset value. For example, all memory blocks in NAND flash memory can be traversed to obtain usage status of each memory block. For memory blocks that are in use, information about the currently used word line (Word Line) can be further obtained. Then, based on a pre-created correspondence between memory pages and regions, a target memory page is matched for the word line being currently used, and read operations are performed on the target memory page using a reference voltage candidate table (containing multiple candidate reference voltages) in the flash memory quality grading apparatus. Each read operation uses a different reference voltage, and the corresponding bit error count is recorded. Finally, the bit error count corresponding to all read operations is statistically analyzed, and the reference voltage corresponding to the minimum bit error count is identified as read voltage offset value amount in the current usage phase.

In one embodiment, a preliminary screening of the above-mentioned plurality of flash memory dies can also be performed. For example, only the flash memory dies with ECC values within the range of 0-80 bits and read voltage offset value within the range of 0-0.2V can be selected. This is because a classification standard for the quality of pages in flash memory dies is that values below 20 bits are optimal and suitable for PCIE-class terminal storage products, values between 21-60 bits are suitable for SATA-class terminal storage products, and values between 61-80 bits are suitable for USB-class terminal storage products. Correspondingly, read voltage offset value AV between 0-0.06V is optimal, between 0.06-0.12V is secondary, and between 0.12-0.2V is the worst. Therefore, they can be used for PCIE-class terminal storage products, SATA-class terminal storage products, and USB-class terminal storage products in sequence. In the prior art, the quality of the flash memory dies is often evaluated only through a single indicator, whereas the disclosure can further combine the above two indicators to calculate evaluation scores, thereby performing subsequent quality classification on the flash memory dies.

In step 102: calculating a normalized value of the bit error count and a normalized value of the read voltage offset value for each of the plurality of flash memory dies.

In one embodiment, the bit error count and the read voltage offset value for each flash memory die can be normalized separately by the processor. Specifically, linear normalization can be used, such as calculating normalized value of the bit error count and the normalized value of the read voltage offset value for each flash memory die based on maximum and minimum values of all bit error count and maximum and minimum values of all read voltage offset value correspondingly, converting these values into a common interval, typically [0, 1].

In other embodiments, standard deviation normalization can also be used, which is achieved by subtracting averages of the original data from each original data and dividing by a standard deviation. This method converts the data into a form with a averages of 0 and a standard deviation of 1, suitable for data distributions that approximate a normal distribution. Decimal scaling normalization can also be used. First, finding the maximum value in the data, then determine how many decimal places need to be shifted to make this value 1 (or a number close to but less than 1). Then, apply the same decimal point shift to all bit error count and read voltage offset value to complete the normalization. This embodiment does not further limit this.

In step 103: assigning a first weight value for the bit error count and a second weight value for the read voltage offset value based on an application type, and calculating an evaluation score for each of the plurality of flash memory dies based on the normalized value of the bit error count, the normalized value of the read voltage offset value, the first weight value, and the second weight value.

In one embodiment, the first weight value for the bit error count and the second weight value for the read voltage offset value can be assigned based on applications of the flash memory dies. Among them, the bit error count is crucial for ensuring data integrity and reliability, while the read voltage offset value may directly affect the read/write stability and lifespan of the flash memory dies. Therefore, for long-term data storage applications, data integrity and durability are more important, so the weight of the bit error count will be higher. In applications that require fast read/write operations (such as the cache layer of an SSD), the read voltage offset value is not the primary consideration, and the weight of the bit error count can be set higher to balance performance and reliability. In resource-constrained embedded systems, the read voltage offset value directly affects power consumption and stability, so its weight can be set higher. For example, if data reliability is the primary consideration, the weight of the bit error count can be set to 0.7, and the weight of the read voltage offset value can be set to 0.3.

In practical applications, the weights assignment can be performed through one of the following methods: 1. Analytic Hierarchy Process (AHP), which decomposes complex decision factors into different constituent factors and determines the relative importance of each factor through pairwise comparisons to calculate weights. 2. Data-driven method, which automatically calculates the weights of the bit error count and the read voltage offset value based on a large amount of test data and statistical analysis results through machine learning or statistical methods.

After the weights assignment for the bit error count and the read voltage offset value, comprehensive evaluation scores for each flash memory die can be further calculated based on the normalized value of the bit error count, the normalized value of the read voltage offset value, and their respective corresponding weights.

In step 104: categorizing the plurality of flash memory dies into a plurality of quality grades based on the evaluation score of each flash memory die.

In one embodiment, after obtaining the evaluation score of each flash memory die, a clustering algorithm can be used to divide the plurality of flash memory dies into a preset number of classifications. The clustering algorithms include K-means clustering, hierarchical clustering (such as AGNES or DIANA), DBSCAN, etc. Taking the K-means clustering algorithm as an example, first, determine how many classifications (e.g., K classifications) the flash memory dies are to be divided into based on the application scenario or business requirements. Then, randomly select the evaluation score of K flash memory dies as initial centroids, assigning each evaluation score to a cluster corresponding to its nearest initial centroid to form a preset number of clusters, and updating the clusters and centroids until a convergence condition is met At this time, the quality of the clustering results can be evaluated, specifically using indicators such as the Silhouette Coefficient to measure the compactness and separation of the clusters to check if any clusters appear abnormal. If there are no abnormalities, the flash memory dies can be divided into K groups based on the final clustering results.

In one embodiment, after obtaining the evaluation score of each flash memory die, in order to further analyze and optimize the classification of the flash memory dies, the variance of the evaluation scores within each classification and the mean difference of the evaluation scores between classifications can also be calculated. These statistical measures are used to assess the rationality of the classifications and adjust the number of classifications based on the aforementioned variance and mean difference. Specifically, for each classification, the evaluation scores of all flash memory dies within it can be collected, and the mean value of these evaluation scores, i.e., the averages of the classification, can be calculated. The square of the differences between each evaluation score and the mean value is then calculated, and the mean value of the squares of the differences is taken to obtain the variance. If the variance of a certain classification is very large, it indicates that the performance of the flash memory dies within that classification varies significantly. If the variances of all classifications are relatively small, it indicates that the classifications are relatively reasonable. Furthermore, when calculating the mean difference of the evaluation scores of flash memory dies between classifications, for each classification, the mean value of the evaluation scores of the flash memory dies within it can be calculated, and then the absolute value of the difference between the mean values of any two classifications can be calculated to obtain the mean difference. If the mean difference between classifications is very small, it indicates that there is no significant difference in performance among these classifications. If the mean difference is large, it indicates that there are significant performance differences between the classifications, and the classifications are relatively reasonable.

Based on the aforementioned variance and mean difference, when adjusting the number of classifications, if the mean difference between certain classifications is very small and the variance within these classifications is also small, these classifications can be merged into a larger classification. If the variance within a certain classification is very large, indicating that the performance of the flash memory dies within that classification varies significantly, then the classification can be further subdivided based on other criteria (such as performance parameters, application scenarios, etc.).

In this embodiment, the steps 102-104 are performed by the processor.

From the above, it can be seen that the flash memory quality grading method provided in the embodiments of the disclosure can obtain, by the memory controller, the bit error count and the read voltage offset value corresponding to each of a plurality of flash memory dies. Then, the normalized value of the bit error count and the normalized value of the read voltage offset value for each flash memory die are obtained by the processor. The first weight value for the bit error count and the second weight value for the read voltage offset value are obtained, and an evaluation score for each flash memory die is obtained based on the normalized value of the bit error count, the normalized value of the read voltage offset value, the first weight value and the second weight value. A test result for the plurality of flash memory dies is obtained based on the evaluation score of each flash memory die. The solution provided in the embodiments of the disclosure can perform a normalized weighted average on the bit error count and the read voltage offset value of the flash memory dies to calculate corresponding evaluation scores and classify them based on these evaluation scores, thereby improving the accuracy of the classification of the flash memory dies.

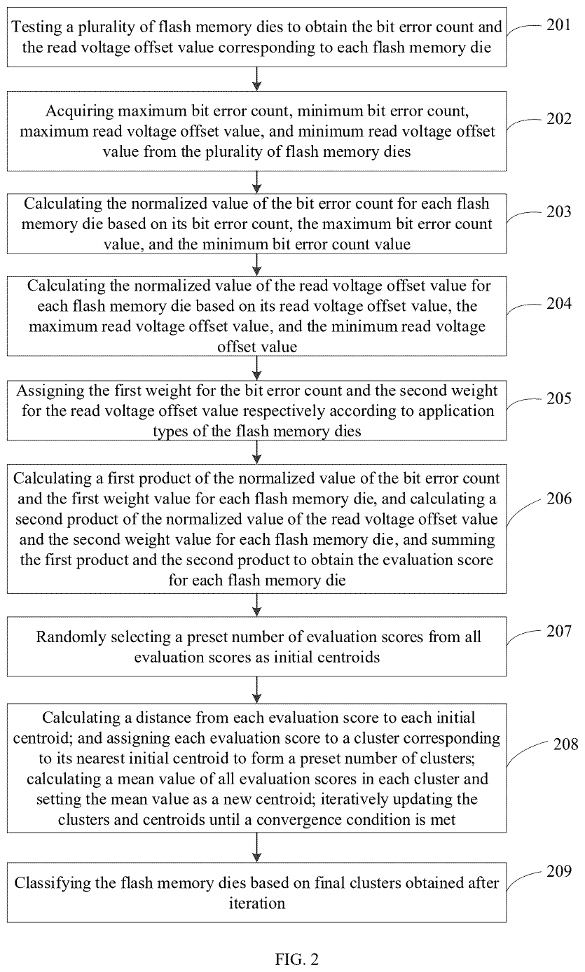

Referring to FIG. 2, which is another flowchart diagram of the flash memory quality grading method provided in the embodiments of the disclosure. The specific flow of the method can be as follows:

In step 201: testing a plurality of flash memory dies to obtain the bit error count and the read voltage offset value corresponding to each flash memory die.

In one embodiment, a preliminary screening of the above-mentioned plurality of flash memory dies can also be performed. For example, only memory dies with ECC values within the range of 0-80 bits and the read voltage offset value within the range of 0-0.2V can be selected. For instance, if the above-mentioned plurality of flash memory dies consists of ten dies, their corresponding bit error count (ECC) and read voltage offset value (ΔV) are as follows:

| Die No. | ECC Value | ΔV Value |
|---|---|---|
| D0 | 12 | 0.00 |
| D1 | 34 | 0.02 |
| D2 | 56 | 0.04 |
| D3 | 23 | 0.06 |
| D4 | 67 | 0.08 |
| D5 | 8 | 0.10 |
| D6 | 45 | 0.12 |
| D7 | 19 | 0.14 |
| D8 | 73 | 0.16 |
| D9 | 31 | 0.18 |

For the dies with serial numbers D0-D9 mentioned above, the ECC values are as follows: D0: 12, D1: 34, D2: 56, D3: 23, D4: 67, D5: 8, D6: 45, D7: 19, D8: 73, D9: 31; and the read voltage offset value ΔV are as follows: D0: 0.00, D1: 0.02, D2: 0.04, D3: 0.06, D4: 0.08, D5: 0.10, D6: 0.12, D7: 0.14, D8: 0.16, D9: 0.18.

In step 202: acquiring a maximum bit error count value, a minimum bit error count value, a maximum read voltage offset value, and a minimum read voltage offset value from the plurality of flash memory dies.

From the aforementioned data, it can be seen that the minimum ECC value among the dies D0-D9 is 8, and the maximum is 73. The minimum read voltage offset value ΔV is 0.00, and the maximum is 0.18.

In step 203: calculating the normalized value of the bit error count for each flash memory die based on its bit error count, the maximum bit error count value, and the minimum bit error count value.

In step 204: calculating the normalized value of the read voltage offset value for each flash memory die based on its read voltage offset value, the maximum read voltage offset value, and the minimum read voltage offset value.

In one embodiment, for the ECC value of each flash memory die, the normalization formula is:

$$E C {C}_{n o r m} = \frac{E C C - E C {C}_{min}}{E C {C}_{max} - E C {C}_{min}}$$

Where ECCₙₒᵣₘ is the normalized value of the bit error count for the flash memory die, ECC is the bit error count for that flash memory die, ECCₘᵢₙ is the minimum bit error count among the plurality of flash memory dies, and ECCₘₐₓ is the maximum bit error count among the plurality of flash memory dies.

Furthermore, for the read voltage offset value ΔV of each flash memory die, the normalization formula is:

$$Δ {V}_{n o r m} = \frac{Δ V - Δ {V}_{min}}{Δ {V}_{max} - Δ {V}_{min}}$$

Where ΔVₙₒᵣₘ is the normalized value of the read voltage offset value for the flash memory die, ΔV is the read voltage offset value for that flash memory die, ΔVₘᵢₙ is the minimum offset data among the plurality of flash memory dies, and ΔVₘₐₓ is the maximum offset data among the plurality of flash memory dies.

For example, for the die with serial number D0, where ECC is 12 and ΔV is 0.00, substituting these values into the two formulas above for normalization yields ECCₙₒᵣₘ=0.0615 and ΔVₙₒᵣₘ=0.

In step 205: assigning the first weight for the bit error count and the second weight for the read voltage offset value respectively according to application types of the flash memory dies.

In step 206: calculating a first product of the normalized value of the bit error count and the first weight value for each flash memory die, and calculating a second product of the normalized value of the read voltage offset value and the second weight value for each flash memory die, and summing the first product and the second product to obtain the evaluation score for each flash memory die.

In one embodiment, the first weight value for the bit error count and the second weight value for the read voltage offset value can be assigned based on the application of the flash memory dies. For example, the weight for the bit error count can be set to 0.5, and similarly, the weight for the read voltage offset value can be set to 0.5, indicating that the two indicators, the bit error count and the read voltage offset value, have equal importance in calculating the evaluation scores. At this point, the calculation 0.0615*0.5+0*0.5=0.03075 can be performed, which is the evaluation score corresponding to the flash memory die with serial number D0. By analogy, the comprehensive evaluation scores for all ten dies in the above list are calculated as follows:

| Die No. | Evaluation Score |
|---|---|
| D0 | 0.03076923076923077 |
| D1 | 0.3230769230769231 |
| D2 | 0.6846153846153846 |
| D3 | 0.19230769230769232 |
| D4 | 0.8307692307692308 |
| D5 | 0.000000000000000 |
| D6 | 0.5153846153846154 |
| D7 | 0.13846153846153846 |
| D8 | 0.8846153846153846 |
| D9 | 0.29230769230769234 |

In step 207: randomly selecting a preset number of evaluation scores from all evaluation scores as initial centroids.

In step 208: calculating a distance from each evaluation score to each initial centroid; assigning each evaluation score to a cluster corresponding to its nearest initial centroid to form a preset number of clusters.

From the above results, D5 (with a evaluation score of 0) is the sample with the lowest evaluation score, while D8 (with a evaluation score of 0.88462) is the sample with the highest evaluation score. Furthermore, based on the comprehensive evaluation score in the table, further the classification can be performed, specifically dividing them into three classifications. Each category corresponds to flash memory dies suitable for different terminal devices. In one embodiment, the classification is done via the K-means clustering algorithm. The K-means clustering algorithm is an unsupervised learning algorithm used to group the flash memory dies into K clusters, where K is the pre-specified number of clusters. In this embodiment, K=3. Specifically, K evaluation scores are randomly selected as initial centroids. In this embodiment of the disclosure, K=3, so three evaluation scores need to be randomly selected as initial centroids. Then, each evaluation score is assigned to the cluster with the nearest centroids. Specifically, calculating a mean value of the three evaluation scores in each cluster and setting the mean value as a new centroid; and iteratively updating the clusters and centroids until a convergence condition is met.

The iteratively updating the clusters and centroids include: calculating a distance from each evaluation score to each current centroid; reassigning each evaluation score to a cluster corresponding to its nearest current centroid; calculating a new mean value of all evaluation scores in each new cluster and setting the new mean value as an updated centroid; repeating the calculating, reassigning, and calculating steps until the centroids remain substantially unchanged between iterations.

In step 209: classifying the flash memory dies based on final clusters obtained after iteration.

Classifying the flash memory dies based on the final clusters includes: identifying flash memory dies in a cluster associated with a centroid having a smallest value as a highest quality grade; identifying flash memory dies in a cluster associated with a centroid having a next smallest value as a medium quality grade; and identifying flash memory dies in a cluster associated with a centroid having a largest value as a lowest quality grade.

Furthermore, the process of assigning evaluation scores and updating centroids is repeated until the centroids stabilize or the maximum number of iterations is reached. When the iteration is completed, the final clusters are output as the preset number of classifications. Taking the preset number as 3 as an example, identifying flash memory dies in a cluster associated with a centroid having a smallest value as a highest quality grade; identifying flash memory dies in a cluster associated with a centroid having a next smallest value as a medium quality grade; and identifying flash memory dies in a cluster associated with a centroid having a largest value as a lowest quality grade.

For example, three evaluation scores can be randomly selected from the list of evaluation score corresponding to the above ten flash memory dies as initial centroids. Specifically, D0, D5, and D8 can be selected as initial centroids, i.e., initial centroids C0:D0=0.03076923076923077, initial centroids C1:D5=0.000000000000000, and initial centroids C2:D8=0.8846153846153846. The distances from each evaluation score to these three centroids are calculated, and they are assigned to the nearest centroids. The distances can be the absolute differences between the values. For each cluster, the average of all evaluation scores of each cluster is calculated, and this average is taken as the new centroids for each cluster.

Specifically, during the first iteration, D0 is assigned to C0, D1 to C0, D2 to C2, D3 to C0, D4 to C2, D5 to C1, D6 to C2, D7 to C0, D8 to C2, and D9 to C0. Then, the centroids are updated, and after calculation, C0=0.1892, C1=0, and C2=0.7289 are obtained. Using these updated centroids, a second iteration is performed. Specifically, D0 is assigned to C0, D1 to C0, D2 to C2, D3 to C0, D4 to C2, D5 to C1, D6 to C2, D7 to C0, D8 to C2, and D9 to C0. The centroids are updated again, and after calculation, C0=0.1892, C1=0, and C2=0.7289 are obtained. It can be seen that after two iterations, the centroids have not changed, indicating that a stable state has been reached, and the iteration is ended. Therefore, the final cluster division is as follows: Cluster 1 (C0) includes D0, D1, D3, D7, D9; Cluster 2 (C1) includes D5; Cluster 3 (C2) includes D2, D4, D6, D8. Among them, Cluster 1 (C0) contains flash memory dies with relatively small evaluation scores, which can be classified for SATA-type storage products. Cluster 2 (C1) contains flash memory dies with the smallest evaluation score, which can be classified for PCIE-type storage products. Cluster 3 (C2) contains flash memory dies with relatively large evaluation scores, which can be classified for USB-type storage products.

This embodiment can use the two indicators of ECC value and read voltage offset value ΔV to evaluate the quality of dies and classify these dies based on their comprehensive evaluation scores, thereby facilitating the subsequent use of flash memory dies for manufacturing storage products corresponding to their quality grades according to the quality of the dies.

All the aforementioned technical solutions can be combined in any manner to form optional embodiments of the disclosure, which will not be elaborated one by one here.

From the above, it can be seen that the flash memory quality grading method provided in the embodiments of the disclosure can obtain the bit error count and the read voltage offset value corresponding to each of a plurality of flash memory dies, obtain the maximum and minimum values of the bit error count, as well as the maximum and minimum values of the read voltage offset value among the plurality of flash memory dies, calculate the normalized value of the bit error count based on each bit error count, the maximum bit error count, and the minimum bit error count, calculate the normalized value of the read voltage offset value based on each read voltage offset value, the maximum read voltage offset value, and the minimum read voltage offset value, assign weights to the bit error count and the read voltage offset value based on the application type of the flash memory dies, calculate the first product of the normalized value of the bit error count and its corresponding weight value, as well as the second product of the normalized value of the read voltage offset value and its corresponding weight value for each flash memory die, take the sum of the first product and the second product as the evaluation scores of the flash memory dies, randomly select a preset number of evaluation scores from the evaluation scores of all flash memory dies as initial centroids, calculate a distance from each evaluation score to each initial centroid; assigning each evaluation score to a cluster corresponding to its nearest initial centroid to form a preset number of clusters, calculating a mean value of all evaluation scores in each cluster and setting the mean value as a new centroid; iteratively updating the clusters and centroids until a convergence condition is met; and classifying the flash memory dies based on final clusters obtained after iteration. The solution provided in the embodiments of the disclosure can perform a normalized weighted average on the bit error count and the read voltage offset value of the flash memory dies to calculate corresponding evaluation scores and classify them based on these values, thereby improving the accuracy of the classification of the flash memory dies.

To implement the above method, an embodiment of the disclosure also provides a flash memory quality grading apparatus.

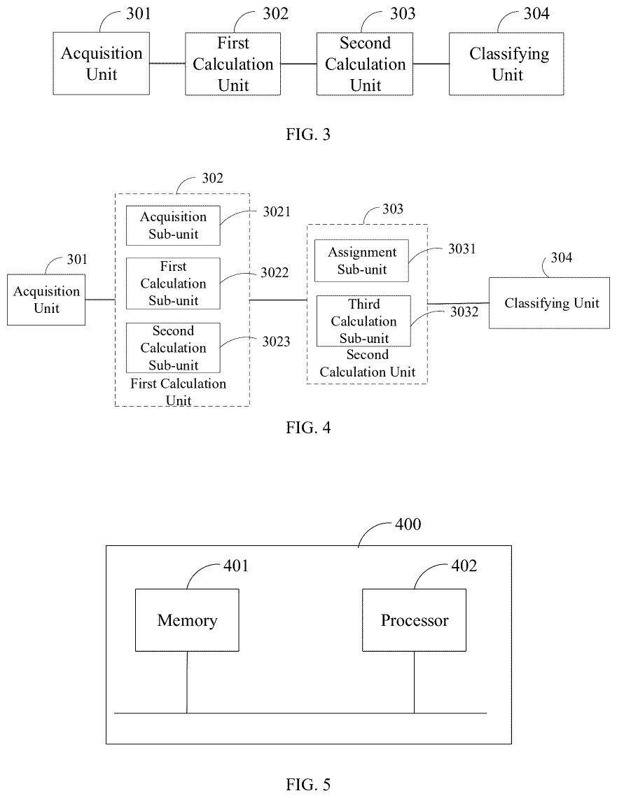

For example, as shown in FIG. 3, it is the first structural schematic diagram of the flash memory quality grading apparatus provided by an embodiment of the disclosure. The flash memory quality grading apparatus is applied to a storage device, which includes a memory controller and a processor. And the flash memory quality grading apparatus specifically may include:
An acquisition unit 301, configured to test a plurality of flash memory dies to obtain a bit error count and a read voltage offset value corresponding to each flash memory die;
A first calculation unit 302, configured to calculate a normalized value of the bit error count and a normalized value of the read voltage offset value for each of the plurality of flash memory dies;
A second calculation unit 303, configured to assign a first weight value for the bit error count and a second weight value for the read voltage offset value based on an application type, and calculate an evaluation score for each of the plurality of flash memory dies based on the normalized value of the bit error count, the normalized value of the read voltage offset value, the first weight value, and the second weight value.

A classifying unit 304, configured to categorize the plurality of flash memory dies into a plurality of quality grades based on the evaluation score of each flash memory dies.

In an embodiment, referring to FIG. 4, which is the second structural schematic diagram of the flash memory quality grading apparatus provided by an embodiment of the disclosure, wherein:
The first calculation unit 302 may specifically include:
An acquisition sub-unit 3021, configured to acquire a maximum bit error count value, a minimum bit error count value, a maximum read voltage offset value, and a minimum read voltage offset value from the plurality of flash memory dies;
A first calculation sub-unit 3022, configured to calculate the normalized value of the bit error count for each flash memory die based on its bit error count, the maximum bit error count value, and the minimum bit error count value;
A second calculation sub-unit 3023, configured to calculate the normalized value of the read voltage offset value for each flash memory die based on its read voltage offset value, the maximum read voltage offset value, and the minimum read voltage offset value.

Furthermore, the above second calculation unit 303 may specifically include:
An assignment sub-unit 3031, configured to assign a first weight value for the bit error count and a second weight value for the read voltage offset value based on an application type;
A third calculation sub-unit 3032, configured to calculate a first product of the normalized value of the bit error count and the first weight value for each flash memory die; calculate a second product of the normalized value of the read voltage offset value and the second weight value for each flash memory die; and sum the first product and the second product to obtain the evaluation score for each flash memory die.

The flash memory quality grading apparatus provided by the embodiment of the disclosure can enable the memory controller to obtain the bit error count and the read voltage offset value corresponding to each flash memory die, then enable the processor to calculate the normalized value of the bit error count and the normalized value of the read voltage offset value for each flash memory die, assign the weights of the bit error count and the read voltage offset value by the processor, calculate the evaluation score for each flash memory die based on the normalized value of the bit error count, the normalized value of the read voltage offset value, and the weight values, and categorize the plurality of flash memory dies into a plurality of quality grades based on the evaluation score of each flash memory die. The solution provided by an embodiment of the disclosure can perform normalized weighted averaging on the bit error count and the read voltage offset value of the flash memory dies to calculate the corresponding evaluation scores and classify them based on these values, thereby improving the accuracy of flash memory die classification.

All the technical solutions mentioned above may be combined in any manner to form optional embodiments of the disclosure, which will not be elaborated one by one here.

An embodiment of the disclosure also provides a computer device, including a memory and a processor. The processor performs the flash memory quality grading method provided by this embodiment by invoking computer programs stored in the memory.

For example, the above computer device may be a terminal device with corresponding functions such as a mobile phone, a tablet computer, a personal computer, a cloud computer, etc. Referring to FIG. 5, which is the structural schematic diagram of the computer provided by an embodiment of the disclosure.

The computer device 400 may include components such as a memory 401 and a processor 402. Those skilleding to each flash memory die;

Calculating a normalized value of the bit error count and a normalized value of the read voltage offset value for each of the plurality of flash memory dies.

Assigning a first weight value for the bit error count and a second weight value for the read voltage off in the art can understand that the structure of the computer device shown in FIG. 5 does not constitute a limitation on the computer device and may include more or fewer components than illustrated, or some components may be combined, or different component arrangements may be made.

The memory 401 may be configured to store applications and data. The applications stored in the memory 401 contain computer program. The applications can form various functional modules. The processor 402 executes various functional applications and data processing by running the applications stored in the memory 401.

The processor 402 is the control center of the computer device, connecting various parts of the entire computer device using various interfaces and lines. By running or executing the applications stored in the memory 401 and invoking the data stored in the memory 401, the processor 402 executes various functions and processes data of the computer device, thereby performing overall monitoring of the computer device.

In this embodiment, the processor 402 in the computer device will load the executable code corresponding to the processes of one or more applications into the memory 401 according to the following instructions and run the applications stored in the memory 401 by the processor 402 to execute:
Testing a plurality of flash memory dies to obtain a bit error count and a read voltage offset value corresponding to each flash memory die;
Calculating a normalized value of the bit error count and a normalized value of the read voltage offset value for each of the plurality of flash memory dies;
Assigning a first weight value for the bit error count and a second weight value for the read voltage offset value based on an application type;
Calculating an evaluation score for each of the plurality of flash memory dies based on the normalized value of the bit error count, the normalized value of the read voltage offset value, the first weight value, and the second weight value; and
Categorizing the plurality of flash memory dies into a plurality of quality grades based on the evaluation score of each flash memory die.

Those skilled in the art can understand that all or part of the steps in the various methods of the above embodiments may be completed by instructions or by controlling relevant hardware through instructions. The instructions may be stored in a computer-readable non-transitory computer-readable storage medium and loaded and executed by the processor.

To this end, an embodiment of the disclosure provides a non-transitory computer-readable storage medium in which multiple instructions are stored. These instructions can be loaded by the processor to execute the steps in any of the flash memory quality grading methods provided by the embodiments of the disclosure. For example, the instructions may execute the following steps:
Testing a plurality of flash memory dies to obtain a bit error count and a read voltage offset value correspond set value based on an application type;
Calculating an evaluation score for each of the plurality of flash memory dies based on the normalized value of the bit error count, the normalized value of the read voltage offset value, the first weight value, and the second weight value; and
Categorizing the plurality of flash memory dies into a plurality of quality grades based on the evaluation score of each flash memory die.

The specific implementations of the above operations can be referred to in the previous embodiments and will not be elaborated here.

The non-transitory computer-readable storage medium may include: Read Only Memory (ROM), Random Access Memory (RAM), magnetic disks, optical disks, etc.

Since the instructions stored in the non-transitory computer-readable storage medium can execute the steps in any of the flash memory quality grading methods provided by the embodiments of the disclosure, the beneficial effects that can be achieved by any of the flash memory quality grading methods provided by the embodiments of the disclosure can be realized. For details, referring to the previous embodiments, which will not be elaborated here.

In the embodiments of the flash memory quality grading apparatus and the readable non-transitory computer-readable storage medium provided by the disclosure, they contain all the technical features of the various embodiments of the above method. The content of the specification expansion and explanation is the same as the adaptability of the various embodiments of the above flash memory quality grading method and will not be elaborated here again.

An embodiment of the disclosure also provides a chip, including a memory and a processor. The memory is used to store programs, and the processor is used to invoke and run the programs from the memory, enabling the device equipped with the chip to execute the methods in various possible embodiments as described above.

In the above embodiments, the descriptions of each embodiment have their own focuses. For parts not detailed in a certain embodiment, reference can be made to the detailed description of the flash memory quality grading apparatus above, which will not be elaborated here again.

The flash memory quality grading apparatus provided by the embodiments of the disclosure belongs to the same concept as the flash memory quality grading method in the above embodiments. Its specific implementation process is detailed in the embodiments of the flash memory quality grading method and will not be elaborated here again.

It should be noted that for the flash memory quality grading method provided by the embodiments of the disclosure, those skilled in the art can understand that all or part of the process of implementing the flash memory quality grading method provided by the embodiments of the disclosure can be completed by controlling relevant hardware through computer programs. The computer programs may be stored in a computer-readable non-transitory computer-readable storage medium, such as in the memory, and executed by at least one processor. During the execution process, it may include the process of the embodiments of the flash memory quality grading method. The non-transitory computer-readable storage medium may be a magnetic disk, an optical disk, Read Only Memory (ROM), Random Access Memory (RAM), etc.

The above provides a detailed introduction to the flash memory quality grading method, the flash memory quality grading apparatus, the non-transitory computer-readable storage medium, and the computing device provided by the embodiments of the disclosure. Specific examples are used to elaborate on the principles and implementation methods of the disclosure. The descriptions of the above embodiments are only used to help understand the methods and core ideas of the disclosure. Meanwhile, for those skilled in the art, there may be changes in the specific implementation methods and application scopes according to the ideas of the disclosure. In summary, the content of this specification should not be understood as a limitation on the disclosure.

The above descriptions are only embodiments of the disclosure and do not thereby limit the patent protection scope of the disclosure. Any equivalent structures or equivalent process transformations made using the content of the specification and drawings of the disclosure, such as the mutual combination of technical features among various embodiments, or direct or indirect application in other related technical fields, are all included in the patent protection scope of the disclosure.

1. A flash memory quality grading method, comprising:
testing a plurality of flash memory dies to obtain a bit error count and a read voltage offset value corresponding to each flash memory die;
calculating a normalized value of the bit error count and a normalized value of the read voltage offset value for each of the plurality of flash memory dies;
assigning a first weight value for the bit error count and a second weight value for the read voltage offset value based on an application type;
calculating an evaluation score for each of the plurality of flash memory dies based on the normalized value of the bit error count, the normalized value of the read voltage offset value, the first weight value, and the second weight value; and
categorizing the plurality of flash memory dies into a plurality of quality grades based on the evaluation score of each flash memory die.

2. The method of claim 1, wherein calculating the normalized value of the bit error count and the normalized value of the read voltage offset value comprises:
acquiring a maximum bit error count value, a minimum bit error count value, a maximum read voltage offset value, and a minimum read voltage offset value from the plurality of flash memory dies;
calculating the normalized value of the bit error count for each flash memory die based on its bit error count, the maximum bit error count value, and the minimum bit error count value; and
calculating the normalized value of the read voltage offset value for each flash memory die based on its read voltage offset value, the maximum read voltage offset value, and the minimum read voltage offset value.

3. The method of claim 2, wherein calculating the evaluation score comprises:
calculating a first product of the normalized value of the bit error count and the first weight value for each flash memory die;
calculating a second product of the normalized value of the read voltage offset value and the second weight value for each flash memory die; and
summing the first product and the second product to obtain the evaluation score for each flash memory die.

4. The method of claim 1, wherein categorizing the plurality of flash memory dies comprises:
randomly selecting a preset number of evaluation scores from all evaluation scores as initial centroids;
calculating a distance from each evaluation score to each initial centroid;
assigning each evaluation score to a cluster corresponding to its nearest initial centroid to form a preset number of clusters;
calculating a mean value of all evaluation scores in each cluster and setting the mean value as a new centroid;
iteratively updating the clusters and centroids until a convergence condition is met; and
classifying the flash memory dies based on final clusters obtained after iteration.

5. The method of claim 4, wherein iteratively updating the clusters and centroids comprises:
calculating a distance from each evaluation score to each current centroid;
reassigning each evaluation score to a cluster corresponding to its nearest current centroid;
calculating a new mean value of all evaluation scores in each new cluster and setting the new mean value as an updated centroid; and
repeating the calculating, reassigning, and calculating steps until the centroids remain substantially unchanged between iterations.

6. The method of claim 4, wherein classifying the flash memory dies based on the final clusters comprises:
identifying flash memory dies in a cluster associated with a centroid having a smallest value as a highest quality grade;
identifying flash memory dies in a cluster associated with a centroid having a next smallest value as a medium quality grade; and
identifying flash memory dies in a cluster associated with a centroid having a largest value as a lowest quality grade.

7. The method of claim 4, further comprising:
calculating a variance of evaluation scores within each quality grade;
calculating a mean difference of evaluation scores between different quality grades; and
adjusting a number of the quality grades based on the calculated variances and mean differences.

8. A flash memory quality grading apparatus, comprising:
a memory controller, configured to test a plurality of flash memory dies to obtain a bit error count and a read voltage offset value corresponding to each flash memory die; and
a processor, coupled to the memory controller, and configured to:
calculate a normalized value of the bit error count and a normalized value of the read voltage offset value for each of the plurality of flash memory dies;
assign a first weight value for the bit error count and a second weight value for the read voltage offset value based on an application type;
calculate an evaluation score for each of the plurality of flash memory dies based on the normalized value of the bit error count, the normalized value of the read voltage offset value, the first weight value, and the second weight value; and
categorize the plurality of flash memory dies into a plurality of quality grades based on the evaluation score of each flash memory die.

9. The apparatus of claim 8, wherein calculating the normalized value of the bit error count and the normalized value of the read voltage offset value comprises:
acquiring a maximum bit error count value, a minimum bit error count value, a maximum read voltage offset value, and a minimum read voltage offset value from the plurality of flash memory dies;
calculating the normalized value of the bit error count for each flash memory die based on its bit error count, the maximum bit error count value, and the minimum bit error count value; and
calculating the normalized value of the read voltage offset value for each flash memory die based on its read voltage offset value, the maximum read voltage offset value, and the minimum read voltage offset value.

10. The apparatus of claim 9, wherein calculating the evaluation score comprises:
calculating a first product of the normalized value of the bit error count and the first weight value for each flash memory die;
calculating a second product of the normalized value of the read voltage offset value and the second weight value for each flash memory die; and
summing the first product and the second product to obtain the evaluation score for each flash memory die.

11. The apparatus of claim 8, wherein categorizing the plurality of flash memory dies comprises:
randomly selecting a preset number of evaluation scores from all evaluation scores as initial centroids;
calculating a distance from each evaluation score to each initial centroid;
assigning each evaluation score to a cluster corresponding to its nearest initial centroid to form a preset number of clusters;
calculating a mean value of all evaluation scores in each cluster and setting the mean value as a new centroid;
iteratively updating the clusters and centroids until a convergence condition is met; and
classifying the flash memory dies based on final clusters obtained after iteration.

12. The apparatus of claim 11, wherein iteratively updating the clusters and centroids comprises:
calculating a distance from each evaluation score to each current centroid;
reassigning each evaluation score to a cluster corresponding to its nearest current centroid;
calculating a new mean value of all evaluation scores in each new cluster and setting the new mean value as an updated centroid; and
repeating the calculating, reassigning, and calculating steps until the centroids remain substantially unchanged between iterations.

13. The apparatus of claim 11, wherein classifying the flash memory dies based on the final clusters comprises:
identifying flash memory dies in a cluster associated with a centroid having a smallest value as a highest quality grade;
identifying flash memory dies in a cluster associated with a centroid having a next smallest value as a medium quality grade; and
identifying flash memory dies in a cluster associated with a centroid having a largest value as a lowest quality grade.

14. The apparatus of claim 11, further comprising:
calculating a variance of evaluation scores within each quality grade;
calculating a mean difference of evaluation scores between different quality grades; and
adjusting a number of the quality grades based on the calculated variances and mean differences.

15. A non-transitory computer-readable storage medium storing instructions that, when executed by a processor of a computing device, cause the computing device to perform a flash memory quality grading method, the method comprising:
testing a plurality of flash memory dies to obtain a bit error count and a read voltage offset value corresponding to each flash memory die;
calculating a normalized value of the bit error count and a normalized value of the read voltage offset value for each of the plurality of flash memory dies;
assigning a first weight value for the bit error count and a second weight value for the read voltage offset value based on an application type;
calculating an evaluation score for each of the plurality of flash memory dies based on the normalized value of the bit error count, the normalized value of the read voltage offset value, the first weight value, and the second weight value; and
categorizing the plurality of flash memory dies into a plurality of quality grades based on the evaluation score of each flash memory die.

16. The non-transitory computer-readable storage medium of claim 15, wherein calculating the normalized value of the bit error count and the normalized value of the read voltage offset value comprises:
acquiring a maximum bit error count value, a minimum bit error count value, a maximum read voltage offset value, and a minimum read voltage offset value from the plurality of flash memory dies;
calculating the normalized value of the bit error count for each flash memory die based on its bit error count, the maximum bit error count value, and the minimum bit error count value; and
calculating the normalized value of the read voltage offset value for each flash memory die based on its read voltage offset value, the maximum read voltage offset value, and the minimum read voltage offset value.

17. The non-transitory computer-readable storage medium of claim 16, wherein calculating the evaluation score comprises:
calculating a first product of the normalized value of the bit error count and the first weight value for each flash memory die;
calculating a second product of the normalized value of the read voltage offset value and the second weight value for each flash memory die; and
summing the first product and the second product to obtain the evaluation score for each flash memory die.

18. The non-transitory computer-readable storage medium of claim 15, wherein categorizing the plurality of flash memory dies comprises:
randomly selecting a preset number of evaluation scores from all evaluation scores as initial centroids;
calculating a distance from each evaluation score to each initial centroid;
assigning each evaluation score to a cluster corresponding to its nearest initial centroid to form a preset number of clusters;
calculating a mean value of all evaluation scores in each cluster and setting the mean value as a new centroid;
iteratively updating the clusters and centroids until a convergence condition is met; and
classifying the flash memory dies based on final clusters obtained after iteration.

19. The non-transitory computer-readable storage medium of claim 18, wherein iteratively updating the clusters and centroids comprises:
calculating a distance from each evaluation score to each current centroid; reassigning each evaluation score to a cluster corresponding to its nearest current centroid;
calculating a new mean value of all evaluation scores in each new cluster and setting the new mean value as an updated centroid; and
repeating the calculating, reassigning, and calculating steps until the centroids remain substantially unchanged between iterations.

20. The non-transitory computer-readable storage medium of claim 18, wherein classifying the flash memory dies based on the final clusters comprises:
identifying flash memory dies in a cluster associated with a centroid having a smallest value as a highest quality grade;
identifying flash memory dies in a cluster associated with a centroid having a next smallest value as a medium quality grade; and
identifying flash memory dies in a cluster associated with a centroid having a largest value as a lowest quality grade.
